(19) United States
(12) Patent Application Publication
(10) Pub. No.: US 2016/0322087 A1
(43) Pub. Date: Nov. 3, 2016

(54) DATA STORAGE DEVICE AND OPERATING METHOD THEREOF

(71) Applicant: SK hynix Inc., Gyeonggi-do (KR)

(72) Inventor: Chung Un NA, Gyeonggi-do (KR)

(21) Appl. No.: 14/842,358

(22) Filed: Sep. 1, 2015

(30) Foreign Application Priority Data
Apr. 30, 2015 (KR) 10-2015-0061552

(51) Int. Cl. G11C 7/14

(52) U.S. Cl. CPC G11C 7/14

(57) ABSTRACT

A data storage device includes a nonvolatile memory apparatus including a plurality of pages coupled to a single word line; and a controller suitable for accessing the nonvolatile memory apparatus during one of first and second modes, wherein, the second mode is enabled when the nonvolatile memory apparatus has reached a lifetime limit, and wherein the controller stores the same data in both of a source page and a dummy page during the second mode.

### CROSS-REFERENCES TO RELATED APPLICATION

The present application claims priority under 35 U.S.C. §119(a) to Korean application number 10-2015-0061552, filed on Apr. 30, 2015, in the Korean Intellectual Property Office, which is incorporated herein by reference in its entirety.

### BACKGROUND

1. Technical Field

Various embodiments generally relate to a data storage device, and, more particularly, to a data storage device capable of extending the life of a nonvolatile memory apparatus therein.

2. Related Art

A data storage device stores data provided from an external device in response to a write request from the external device. The data storage device also provides the external device with stored data in response to a read request from the external device. The external device is an electronic device capable of processing data, and may include a computer, a digital camera, a cellular phone and the like. The data storage device may be embedded in the external device, or may be fabricated separately and then coupled to the external device.

The data storage device may be prepared in the form of a Personal Computer Memory Card International Association (PCMCIA) card, a Compact Flash (CF) card, a smart media card, a memory stick, various multimedia cards (MMC, eMMC, RS-MMC, and MMC-Micro), various secure digital cards (SD, Mini-SD, and Micro-SD), a Universal Flash Storage (UFS), a Solid State Drive (SSD) and the like.

The data storage device may include a nonvolatile memory apparatus to store data. Nonvolatile memory is able to retain stored data even without a constant source of power. Nonvolatile memory includes flash memory, such as NAND flash or NOR flash, Ferroelectrics Random Access Memory (FeRAM), Phase-Change Random Access Memory (PCRAM), Magnetoresistive Random Access Memory (MRAM), Resistive Random Access Memory (ReRAM), and the like.

### SUMMARY

In an embodiment of the present invention a data storage device may include: a nonvolatile memory apparatus including a plurality of pages coupled to a single word line; and a controller suitable for accessing the nonvolatile memory apparatus during one of first and second modes, wherein the second mode is enabled when the nonvolatile memory apparatus has reached a lifetime limit, and wherein the controller stores the same data in both of a source page and a dummy page during the second mode.

In an embodiment of the present invention, an operating method for a data storage device including a nonvolatile memory apparatus, which includes a plurality of pages coupled to a single word line, may include: storing data in the plurality of pages during a first mode; enabling a second mode by detecting that the nonvolatile memory apparatus has reached a lifetime limit; and storing data in the plurality of pages during the second mode, wherein the storing of the data in the plurality of pages during the second mode comprises storing the same data in both of a source page and a dummy page.

In an embodiment of the present invention, a data storage device may include: a nonvolatile memory apparatus including a plurality of pages coupled to a single word line; and a controller suitable for accessing the nonvolatile memory apparatus during one of first and second modes, wherein a number of threshold voltage distributions of memory cells during the second mode is less than that during the first mode.

### BRIEF DESCRIPTION OF THE DRAWINGS

FIG. 1 is a block diagram exemplarily illustrating a data storage device in accordance with an embodiment of the present invention.

FIG. 2 is a threshold voltage distribution diagram illustrating write and read operations of a nonvolatile memory apparatus shown in FIG. 1.

FIG. 3 is a flow chart exemplarily illustrating an operating method of a data storage device shown in FIG. 1.

FIG. 4 is a flow chart exemplarily illustrating an operating method of a data storage device shown in FIG. 1 during a lifetime extension mode.

FIG. 5 is a diagram exemplarily illustrating a threshold voltage distribution of memory cells in a data storage device shown in FIG. 1 during a normal mode.

FIGS. 6A and 6B are diagrams exemplarily illustrating various threshold voltage distributions of memory cells in a data storage device shown in FIG. 1 during a lifetime extension mode.

FIG. 7 is a flow chart illustrating a write verification operation of a data storage device shown in FIG. 1 during a lifetime extension mode.

FIG. 8 is a diagram of a threshold voltage distribution memory cells exemplarily illustrating a write verification operation of a data storage device shown in FIG. 1 during a normal mode.

FIGS. 9A and 9B are diagrams of a threshold voltage distribution of memory cells exemplarily illustrating a write verification operation of a data storage device shown in FIG. 1 during a lifetime extension mode.

FIG. 10 is a flow chart illustrating a read operation of a data storage device shown in FIG. 1 during a lifetime extension mode.

FIG. 11A is a diagram of a threshold voltage distribution of memory cells exemplarily illustrating a read operation to LSB and MSB pages of a data storage device shown in FIG. 1 during a normal mode.

FIG. 11B is a diagram of a threshold voltage distribution of memory cells exemplarily illustrating a read operation to LSB and MSB pages of a data storage device shown in FIG. 1 during a lifetime extension mode.

FIG. 12A is a diagram of a threshold voltage distribution of memory cells exemplarily illustrating a read operation to LSB and CSB pages of a data storage device shown in FIG. 1 during a normal mode.

FIG. 12B is a diagram of a threshold voltage distribution of memory cells exemplarily illustrating a read operation to LSB and CSB pages of a data storage device shown in FIG. 1 during a lifetime extension mode.

### DETAILED DESCRIPTION

Hereinafter, a data storage device and an operating method thereof according to the present invention will be described with reference to the accompanying drawings through exemplary embodiments. The present invention may, however, be embodied in different forms and should not be construed as limited to the embodiments set forth herein. Rather, these embodiments are provided to describe the present invention in detail to the extent that a person skilled in the art to which the invention pertains can enforce the technical concepts of the present invention.

It is to be understood that embodiments of the present invention are not limited to the particulars shown in the drawings, that the drawings are not necessarily to scale, and, in some instances, proportions may have been exaggerated in order to more clearly depict certain features of the invention. While particular terminology is used, it is to be appreciated that the terminology is for describing particular embodiments only and is not intended to limit the scope of the present invention.

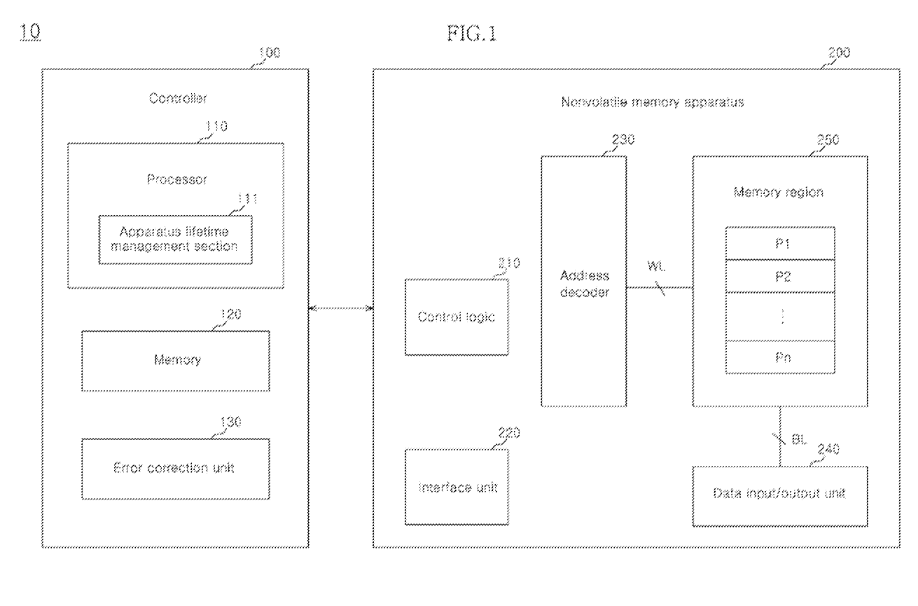

FIG. 1 is a block diagram exemplarily illustrating a data storage device 10 in accordance with an embodiment of the present invention.

The data storage device 10 may include a controller 100 and a nonvolatile memory apparatus 200.

The controller 100 may include a processor 110, a memory 120, and an error correction unit 130.

The processor 110 may control the general operations of the data storage device 10. The processor 110 may access the nonvolatile memory apparatus 200 to control the write operation or the read operation of the nonvolatile memory apparatus 200 in response to a write request or a read request from a host device. The processor 110 may generate a command for controlling the operation of the nonvolatile memory apparatus 200, and provide the generated command to the nonvolatile memory apparatus 200. The processor 110 may drive a software program for controlling the operation of the data storage device 10, on the memory 120.

The processor 110 may include an apparatus lifetime management section 111. The apparatus lifetime management section 111 may count the erase operations performed by the nonvolatile memory apparatus 200, and detect that the nonvolatile memory apparatus 200 has reached a lifetime limit, based on a counting result. For example, the apparatus lifetime management section 111 may detect that the nonvolatile memory apparatus 200 has reached a lifetime limit, when the erase count of the nonvolatile memory apparatus 200 reaches a threshold.

The processor 110 may store data in a plurality of pages corresponding to the same word line in the nonvolatile memory apparatus 200 according to a normal mode or a lifetime extension mode. The processor 110 may store data according to the normal mode until it is detected that the nonvolatile memory apparatus 200 has reached the lifetime limit. Also, the processor 110 may store data according to the lifetime extension mode when it is detected that the nonvolatile memory apparatus 200 has reached the lifetime limit. The controller 100 may store the same data in a source page and a dummy page among the plurality of pages corresponding to the same word line according to the lifetime extension mode. As the controller 100 stores data in the nonvolatile memory apparatus 200 according to the lifetime extension mode, the data reliability of the nonvolatile memory apparatus 200 having reached the lifetime limit may be improved and it is possible to extend the lifetime of the nonvolatile memory apparatus 200.

The memory 120 may serve as a working memory, a buffer memory or a cache memory of the processor 110. The memory 120 as a working memory may store software programs and various program data to be driven by the processor 110. The memory 120 as a buffer memory may buffer the data transmitted between the host device and the nonvolatile memory apparatus 200. The memory 120 as a cache memory may temporarily store cache data.

The error correction unit 130 may encode data before the data are stored in the nonvolatile memory apparatus 200 according to the write request from the host device, such that it is possible to subsequently determine whether an error has occurred in the data and correct it. When the encoded data are read from the nonvolatile memory apparatus 200 according to the read request from the host device, the error correction unit 130 may decode the encoded data and detect and correct an error in the corresponding data.

The nonvolatile memory apparatus 200 may retain stored data even without power. The nonvolatile memory apparatus 200 may include a flash memory apparatus such as a NAND flash or a NOR flash, an FeRAM (ferroelectric random access memory), a PCRAM (phase change random access memory) an MRAM (magnetic random access memory) or an ReRAM (resistive random access memory).

The nonvolatile memory apparatus 200 may include a control logic 210, an interface unit 220, an address decoder 230, a data input/output unit 240, and a memory region 250.

The control logic 210 may control the general operations of the nonvolatile memory apparatus 200 such as a write operation, a read operation and an erase operation, in response to the commands provided from the controller 100.

The interface unit 220 may exchange various control signals including commands and addresses and data with the controller 100. The interface unit 220 may transmit the various control signals and the data inputted thereto, to the internal units of the nonvolatile memory apparatus 200.

The address decoder 230 may decode the row addresses and the column addresses transmitted thereto. The address decoder 230 may control word lines WL to be selectively driven according to decoding results of the row addresses. The address decoder 230 may control the data input/output unit 240 such that bit lines BL are selectively driven according to decoding results of the column addresses.

The data input/output unit 240 may transmit the data transmitted from the interface unit 220, to the memory region 250 through the bit lines BL. The data input/output unit 240 may transmit the data read from the memory region 250 through the bit lines BL, to the interface unit 220.

The memory region 250 may be coupled with the address decoder 230 through the word lines WL, and may be coupled with the data input/output unit 240 through the bit lines BL. The memory region 250 may include a memory cell array of, for example, a three-dimensional structure. The memory region 250 may include a plurality of memory cells, which are respectively disposed at areas where the word lines WL and the bit lines BL cross. The memory cells may be distinguished according to a number of bits for the data stored in each memory cell. For example, the memory cells may be distinguished as single level cells each of which stores 1-bit data, multi-level cells each of which stores 2-bit data, and triple level cells each of which stores 3-bit data.

The memory region 250 may include a plurality of pages P1 to Pn. A page may be accessed by driving a corresponding word line. The number of pages corresponding to one word line, that is, the number of pages to be accessed by driving one word line may vary according to the number of bits for the data stored in each of the memory cells coupled to one word line. In other words, when i-bit data are stored in a single memory cell, “i” number of pages may correspond to the single word line. In this case, the “i” bits for the data stored in the memory cell may correspond to i number of pages, respectively. When each of the memory cells coupled to a single word line stores 3-bit data, that is, the least significant bit (LSB) data, the central significant bit (CSB) data and the most significant bit (MSB) data, the single word line may correspond to 3 pages, that is, an LSB page, a CSB page and an MSB page. The LSB, CSB and MSB data of the memory cells coupled to the single word line may be stored in the LSB, CSB and MSB pages of the single word line, respectively.

While it is illustrated in FIG. 1 that the data storage device 10 includes a single nonvolatile memory apparatus 200, the number of nonvolatile memory apparatuses included in the data storage device 10 not be specifically limited. According to an embodiment, when the data storage device 10 includes a plurality of nonvolatile memory apparatuses, the controller 100 may detect each lifetime limit of the nonvolatile memory apparatuses, may access a nonvolatile memory apparatus under the lifetime limit according to the normal mode, and may access a nonvolatile memory apparatus over the lifetime limit according to the lifetime extension mode.

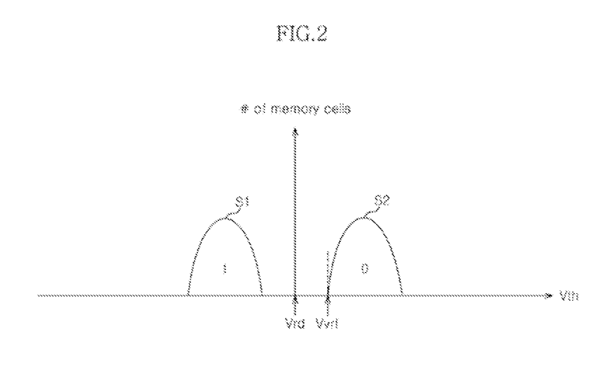

FIG. 2 is a threshold voltage distribution diagram illustrating write and read operations of the nonvolatile memory apparatus 200 shown in FIG. 1. FIG. 2 shows the relationship between threshold voltages Vth of memory cells and the number of memory cells that is, threshold voltage distributions S1 and S2 of the memory cells.

A memory cell may include a gate coupled with a word line and a floating gate for accumulating charges. As a memory cell is applied with a predetermined write voltage through the gate thereof, charges are accumulated in the floating gate, and, when the memory cell has predetermined ranges of threshold voltages, it may be determined that data are stored in the memory cell. A memory cell stored with data may form a certain threshold voltage distribution. For example, when data “1” is stored in the memory cell, the memory cell may form the threshold voltage distribution S1, and, when data “0” is stored in the memory cell, the memory cell may form the threshold voltage distribution S2.

While data is stored in the memory cell, the memory cell may move, for example, from the threshold voltage distribution S1 to the threshold voltage distribution S2. In order to verify that data has been stored in the memory cell when performing the write operation, the control logic 210 may apply a verification voltage Vvrf to the gate of the memory cell and verify whether the memory cell forms the target threshold voltage distribution S2. The verification voltage Vvrf may be a threshold voltage corresponding to the left edge of the target threshold voltage distribution S2. In detail, when the threshold voltage of the memory cell is greater than the verification voltage Vvrf, the control logic 210 may determine that data “0” is stored in the memory cell, and, when the threshold voltage of the memory cell is less than the verification voltage Vvrf, the control logic 210 may determine that data “0” is not stored yet in the memory cell. When it is determined that data “0” is not stored yet in the memory cell, the control logic 210 may apply a write voltage greater than the write voltage previously applied and may thereby raise the threshold voltage of the memory cell.

In order to determine which data has been stored in the memory cell when performing the read operation, the control logic 210 may apply a read voltage Vrd to the gate of the memory cell and determine that the memory cell forms a threshold voltage distribution. The read voltage Vrd may be a threshold voltage that is positioned between the threshold voltage distributions S1 and S2. When the threshold voltage of the memory cell is greater than the read voltage Vrd, the control logic 210 may determine that data “0” is stored in the memory cell, and, when the threshold voltage of the memory cell is less than the read voltage Vrd, the control logic 210 may determine that data “1” is stored in the memory cell.

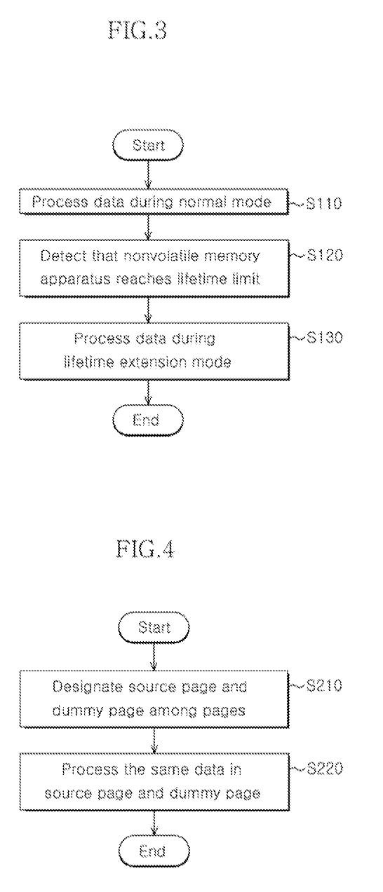

FIG. 3 is a flow chart exemplarily illustrating an operating method of the data storage device 10 shown in FIG. 1.

At step S110, the processor 110 may process data with respect to a plurality of pages corresponding to the single word line according to the normal mode. The process may include write and read operations, which will be described later. When the processor 110 process data with respect to the plurality of pages corresponding to the single word line according to the normal mode, the plurality of memory cells coupled to the corresponding the single word line may form “i” number of threshold voltage distributions. When data are stored in “n” number of pages according to the normal mode, “i” may be 2ⁿ.

At step S120, the processor 110 may detect that the nonvolatile memory apparatus 200 has reached the lifetime limit. For example, the apparatus lifetime management section 111 included in the processor 110 may determine that the nonvolatile memory apparatus 200 has reached the lifetime limit, when the erase count of the nonvolatile memory apparatus 200 reaches a threshold.

At step S130, the processor 110 may process data with respect to the plurality of pages corresponding to the single word line according to the lifetime extension mode. The process may include write and read operations, which will be described later. The processor 110 may process the same data with respect to a part of the plurality of pages, for example, 2 pages among the plurality of pages, according to the lifetime extension mode.

When the processor 110 process the same data with respect to the part of the plurality of pages corresponding to the single word line according to the lifetime extension mode, the plurality of memory cells coupled to the single word line may form “j” number of threshold voltage distributions, which is less than the “i” number of threshold voltage distributions. For example, when data are stored in the n number of pages and the processor 110 stores the same data in 2 pages among the plurality of pages according to the lifetime extension mode, “j” may be 2⁽ⁿ⁻¹⁾.

That is to say, in the data storage device 10 according to the embodiment, when it is detected that the nonvolatile memory apparatus 200 has reached the lifetime limit, the number of threshold voltage distributions to be formed by the memory cells may be decreased according to the lifetime extension mode, whereby it is possible to increase the interval between the threshold voltage distributions. As a consequence, the data storage device 10 may prevent an error in the nonvolatile memory apparatus 200 and increase a read margin, thereby improving data reliability.

FIG. 4 is a flow chart exemplarily illustrating an operating method of the data storage device 10 shown in FIG. 1 during the lifetime extension mode.

At step S210, the processor 110 may designate a source page and a dummy page among a plurality of pages corresponding to the single word line. As will be described later, various embodiments may be established according to which pages among the plurality of pages are to be designated as the source page and the dummy page by the processor 110.

At step S220, the processor 110 may process the same data with respect to the source page and the dummy page. For instance, the processor 110 may store data, which is already stored or is currently to be stored in the source page, in the dummy page as dummy data according to the lifetime extension mode.

As a result, when the data storage device 10 operates according to the lifetime extension mode, user data may be stored in pages except for the dummy page among the plurality of pages. The processor 110 may designate one of a plurality of pages, in which user data are stored, as the source page and may also store the data of the designated source page in the dummy page.

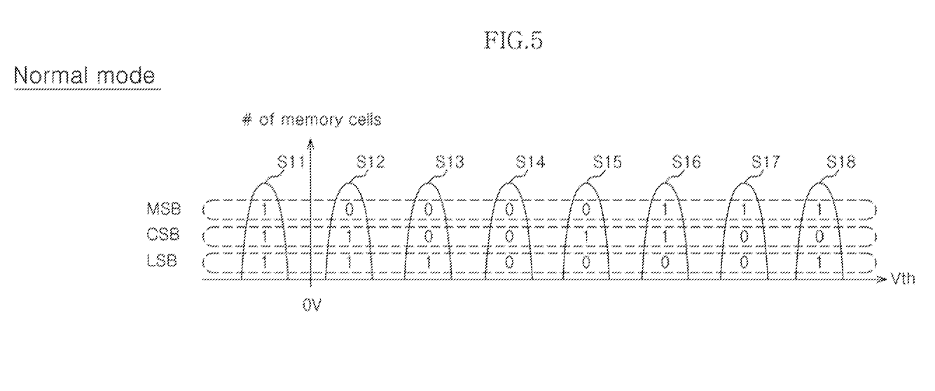

FIG. 5 is a diagram exemplarily illustrating a threshold voltage distribution of memory cells in the data storage device 10 shown in FIG. 1 during the normal mode. In FIG. 5, it is assumed that each of memory cells stores 3-bit data, and accordingly, a single word line may correspond to 3 pages, that is, the LSB, CSB and MSB pages.

Referring to FIG. 5, the memory cell storing data may form predetermined threshold voltage distributions S11 to S18 in the normal mode. When the processor 110 stores data in the LSB, CSB and MSB pages corresponding to the single word line according to the normal mode, the plurality of memory cells coupled to the single word line may form the 2³ threshold voltage distributions S11 to S18. For example, in the normal mode, the memory cell storing data “111” may form the threshold voltage distribution S11, and, the memory cell storing data “011” may form the threshold voltage distribution S12. The threshold voltage distributions S11 to S18 may respectively correspond to predetermined different data “111”, “011”, “001”, “000”, “010”, “110”, “100” and “101”.

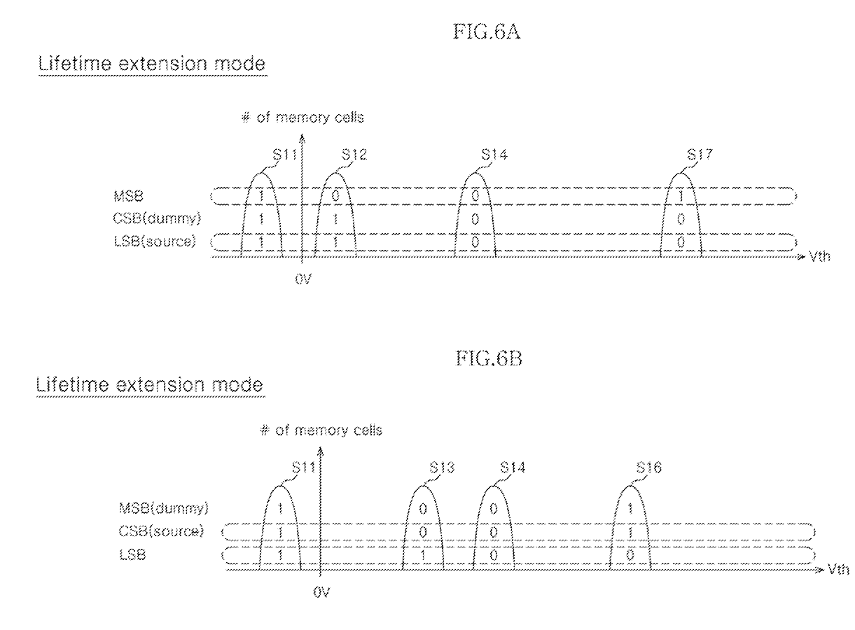

FIGS. 6A and 6B are diagrams exemplarily illustrating various threshold voltage distributions of the memory cells in the data storage device 10 shown in FIG. 1 during the lifetime extension mode. In accordance with an exemplary embodiment of the present invention, during the lifetime extension mode, the processor 110 may store data in various ways described hereunder with reference to FIGS. 6A and 6B. In FIGS. 6A and 6B, it is assumed that each of memory cells stores 3-bit data, and accordingly, the single word line may correspond to the LSB, CSB and MSB pages.

When the processor 110 stores data in the LSB, CSB and MSB pages corresponding to the single word line according to the lifetime extension mode, the plurality of memory cells coupled to the single word line may form 4 threshold voltage distributions. For example, the processor 110 may store the same data in 2 pages among the LSB, CSB and MSB pages according to the lifetime extension mode. Accordingly, during the lifetime extension mode, the plurality of memory cells may form threshold voltage distributions, the number of which is less than those during the normal mode. For example, referring to FIGS. 5 to 6B, the number of threshold voltage distributions is 2³ (the above-described “i”) during the normal mode while the number of threshold voltage distributions is 2⁴ (the above-described “j”) during the lifetime extension mode. The processor 110 may designate a source page and a dummy page among the LSB, CSB and MSB pages according to the lifetime extension mode, and may store data, which is already stored or is currently to be stored in the source page, in the dummy page as the dummy data.

Referring to FIG. 6A, the processor 110 may store data, which is already stored or is currently to be stored in the LSB page, in the CSB page as the dummy data according to the lifetime extension mode. In this case, the memory cells may form 4 threshold voltage distributions S11, S12, S14 and S17. The processor 110 may designate, for example, the LSB page as the source page and the CSB page as the dummy page, and store LSB data in the CSB page as dummy data. User data may be stored in the LSB page and the MSB page.

Referring to FIG. 6B, the processor 110 may store data, which is already stored or is currently to be stored in the CSB page, in the MSB page as the dummy data according to the lifetime extension mode. In this case, the memory cells may form 4 threshold voltage distributions S11, S13, S14 and S16. The processor 110 may designate, for example, the CSB page as the source page and the MSB page as the dummy page, and store CSB data in the MSB page as dummy data. User data may be stored in the LSB page and the CSB page.

According to an embodiment, data may correspond to the threshold voltage distributions of the memory cells according to gray code scheme. Referring to FIG. 5, the data respectively corresponding to the threshold voltage distributions S11 to S18 may be represented by the values of “111”, “011”, “001”, “000”, “010”, “110”, “100” and “101” according to the gray code scheme. According to an embodiment, the data respectively corresponding to the threshold voltage distributions S11 to S18 will not be limited to the values of “111”, “011”, “001”, “000”, “010”, “110”, “100” and “101”, and may be represented by another values according to the gray code scheme.

According to an embodiment, during the lifetime extension mode, the data respectively corresponding to the threshold voltage distributions of the memory cells may be represented by the values according to the gray code scheme, except for the dummy data of the dummy page.

In detail, referring to FIG. 6A, in the data values of “111”, “011”, “000” and “100”, the data values of “11”, “01”, “00” and “10” excluding the dummy data value or the CSB data value may represent the data respectively corresponding to the threshold voltage distributions S11, S12, S14 and S17 according to the gray code scheme.

Referring to FIG. 6B, in the data values of “111”, “001”, “000” and “110”, the data values of “11”, “01”, “00” and “10” excluding the dummy data value or the MSB data value may represent the data respectively corresponding to the threshold voltage distributions S11, S13, S14 and S16 according to the gray code scheme.

According to an embodiment, when selecting the source page and the dummy page to store data according to the lifetime extension mode, the processor 110 may select the LSB and CSB pages or select the CSB and MSB pages as described above with reference to FIGS. 6A and 6B.

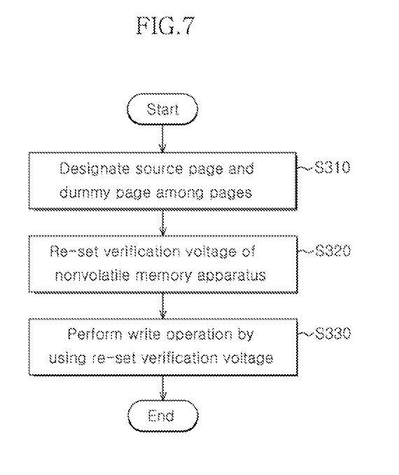

FIG. 7 is a flow chart illustrating a write verification operation of the data storage device 10 shown in FIG. 1 during the lifetime extension mode.

At step S310, the processor 110 may designate the source page and the dummy page among a plurality of pages corresponding to the single word line.

At step S320, the processor 110 may re-set one or more verification voltages to be applied to the single word line in order to allow the nonvolatile memory apparatus 200 to perform the write verification operation. The processor 110 may re-set the verification voltages to increase the margin between the threshold voltage distributions of the memory cells. As will be described later, the verification voltages to be re-set may vary according to which pages are designated as the source and dummy pages among the plurality of pages corresponding to the single word line. In other words, the verification voltages to be re-set may vary according to the threshold voltage distributions during the lifetime extension mode.

At step S330, the nonvolatile memory apparatus 200 may perform the write verification operation by using the re-set verification voltage. The interval between the threshold voltage distributions during the lifetime extension mode may be wider than the interval between the threshold voltage distributions during the normal mode.

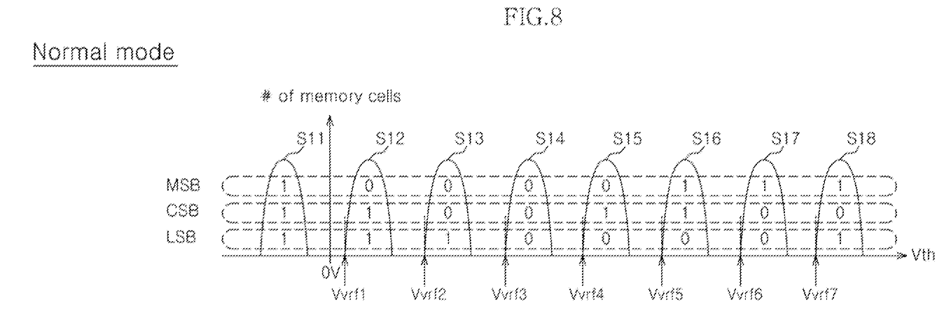

FIG. 8 is a diagram of a threshold voltage distribution of memory cells exemplarily illustrating the write verification operation of the data storage device 10 shown in FIG. 1 during the normal mode.

Referring to FIG. 8, the nonvolatile memory apparatus 200 may use verification voltages Vvrf1 to Vvrf7 to verify whether the threshold voltage distributions S12 to S18 are formed, when storing data during the normal mode.

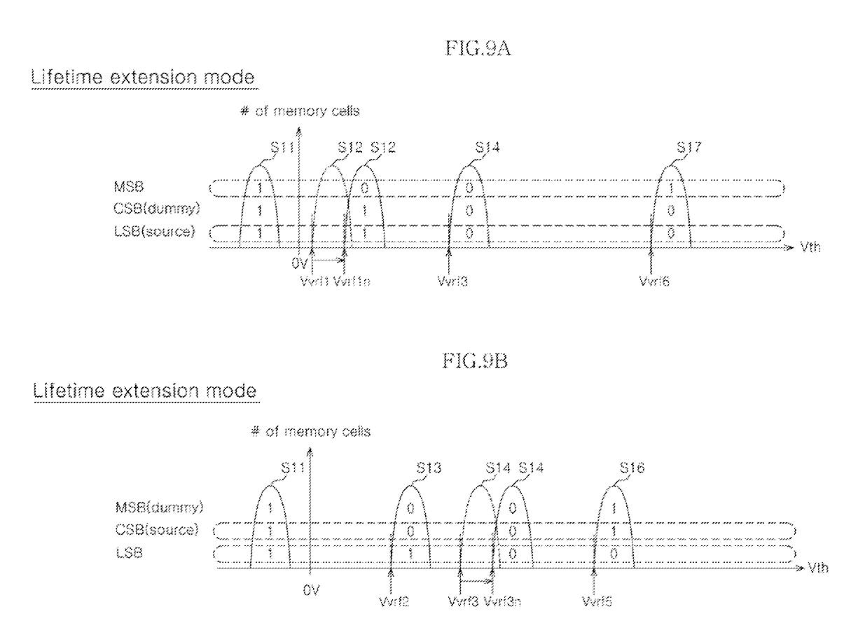

FIGS. 9A and 9B are diagrams of the threshold voltage distribution of memory cells exemplarily illustrating the write operation of the data storage device 10 shown in FIG. 1 during the lifetime extension mode. FIG. 9A shows where the processor 110 stores the data, which is already stored or is currently to be stored in the LSB page, in the CSB page as the dummy data as described above with reference to FIG. 6A. FIG. 9B shows where the processor 110 stores the data, which is already stored or is currently to be stored in the CSB page, in the MSB page as the dummy data as described above with reference to FIG. 6B.

The processor 110 may re-set one or more verification voltages for the nonvolatile memory apparatus 200 to perform the write verification operation during the lifetime extension mode. The processor 110 may re-set the verification voltages before storing data during the lifetime extension mode. The processor 110 may transmit a verification voltage reset command to the nonvolatile memory apparatus 200 for the write verification operation with the re-set verification voltages. The processor 110 may back up the re-set verification voltages in the nonvolatile memory apparatus 200 to subsequently and continuously use the re-set verification voltage.

Referring to FIG. 9A, the processor 110 may re-set the verification voltage from a current one “Vvrf1” to a new one “Vvref1n” for the write verification operation with respect to the threshold voltage distribution S12, before storing the data, which is already stored or is currently to be stored in the LSB page, in the CSB page as the dummy data during the lifetime extension mode. Accordingly, the nonvolatile memory apparatus 200 may use the verification voltages Vvrf3 and Vvrf6 for the verification operation with respect to the threshold voltage distributions S14 and S17 while the nonvolatile memory apparatus 200 may use the re-set verification voltage Vvrf1n instead of the verification voltage Vvrf1 for the verification operation with respect to the threshold voltage distribution S12.

As shown in FIG. 9A, since the interval between the threshold voltage distributions S11 and S12 is increased sufficiently as the verification voltage is re-set to the new one “Vvref1n” occurrence of an error may be prevented even when the memory cells have reached the lifetime limit and thus have distorted threshold voltages.

The processor 110 may re-set the verification voltage according to the designation of the source and dummy pages during the lifetime extension mode.

Referring to FIG. 9B, the processor 110 may re-set the verification voltage from a current one “Vvrf3” to a new one “Vvref3n” for the write verification operation with respect to the threshold voltage distribution S14, before storing the data, which is already stored or is currently to be stored in the CSB page, in the MSB page as the dummy data during the lifetime extension mode. Accordingly, the nonvolatile memory apparatus 200 may use the verification voltages Vvrf2 and Vvrf5 for the verification operation with respect to the threshold voltage distributions S13 and S16 while the nonvolatile memory apparatus 200 may use the re-set verification voltage Vvrf3n instead of the verification voltage Vvrf3 for the verification operation with respect to the threshold voltage distribution S14.

As shown in FIG. 9B, since the interval between the threshold voltage distributions S13 and S14 is increased sufficiently as the verification voltage is re-set to the new one “Vvref3n”, occurrence of an error may be prevented even when the memory cells have reached the lifetime limit and thus have distorted threshold voltages.

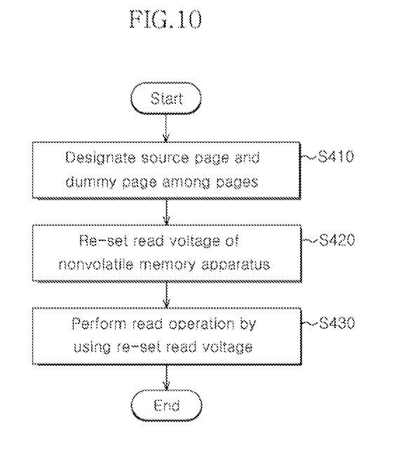

FIG. 10 is a flow chart illustrating a read operation of data storage device 10 shown in FIG. 1 during the lifetime extension mode.

At step S410, the processor 110 may designate the source page and the dummy page among the plurality of pages corresponding to the single word line.

At step S420, the processor 110 may re-set one or more read voltages to be applied to the single word line in order to allow the nonvolatile memory apparatus 200 to perform the read operation. The processor 110 may re-set the read voltages to read the threshold voltage distributions of the memory cells having increased intervals as result of the write verification operation described with reference to FIGS. 9A and 9B. As will be described later, the read voltages to be re-set may vary according to which pages are designated as the source and dummy pages among the plurality of pages corresponding to the single word line. In other words, the read voltages to be re-set may vary according to the threshold voltage distributions during the lifetime extension mode.

At step S430, the nonvolatile memory apparatus 200 may perform the read operation to the threshold voltage distributions, the interval of which is wider than the interval of the threshold voltage distributions during the normal mode, by using the re-set read voltage.

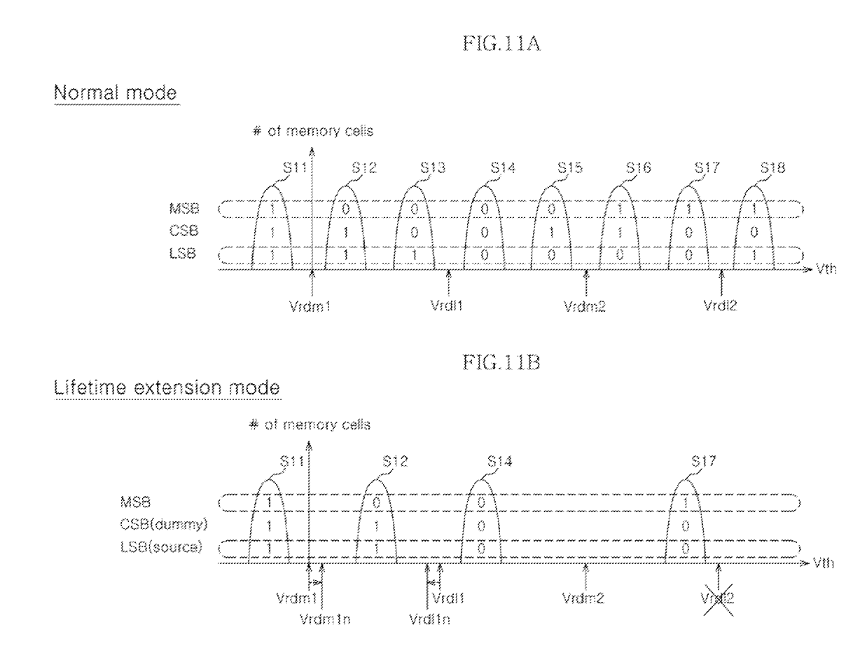

FIG. 11A is a diagram of the threshold voltage distribution of memory cells exemplarily illustrating a read operation to LSB and MSB pages of the data storage device 10 shown in FIG. 1 during the normal mode.

Referring to FIG. 11A, the nonvolatile memory apparatus 200 may use the read voltages Vrdl1 and Vrdl2 when performing the read operation for the LSB page during the normal mode. For example, the nonvolatile memory apparatus 200 may determine that LSB data “1” is stored in the memory cell when the threshold voltage of the memory cell is less than the read voltage Vrdl1, that LSB data “0” is stored in the memory cell when the threshold voltage of the memory cell is greater than the read voltage Vrdl1 and less than the read voltage Vrdl2, and that LSB data “1” is stored in the memory cell when the threshold voltage of the memory cell is greater than the read voltage Vrdl2.

Further, the nonvolatile memory apparatus 200 may use the read voltages Vrdm1 and Vrdm2 when performing the read operation for the MSB page during the normal mode. For example, the nonvolatile memory apparatus 200 may determine that MSB data “1” is stored in the memory cell when the threshold voltage of the memory cell is less than the read voltage Vrdm1, that MSB data “0” is stored in the memory cell when the threshold voltage of the memory cell is greater than the read voltage Vrdm1 and less than the read voltage Vrdm2, and that MSB data “1” is stored in the memory cell when the threshold voltage of the memory cell is greater than the read voltage Vrdm2.

FIG. 11B is a diagram of the threshold voltage distribution of memory cells exemplarily illustrating the read operation to LSB and MSB pages of the data storage device 10 shown in FIG. 1 during the lifetime extension mode. FIG. 11B shows where the processor 110 stores the data, which is already stored or is currently to be stored in the LSB page, in the CSB page as the dummy data as described above with reference to FIG. 6A.

The processor 110 may re-set one or more read voltages for the nonvolatile memory apparatus 200 to perform the read operation to the LSB page and the MSB page during the lifetime extension mode. The processor 110 may re-set the read voltages before reading data during the lifetime extension mode. The processor 110 may transmit a read voltage reset command to the nonvolatile memory apparatus 200 for the read operation with the re-set read voltages. The processor 110 may back up the re-set read voltages in the nonvolatile memory apparatus 200 to subsequently and continuously use the re-set read voltages.

Referring to FIG. 11B, when the verification voltage Vvrf1n for the threshold voltage distribution S12 is re-set as described above with reference to FIG. 9A, the processor 110 may re-set the read voltage from a current one “Vrdm1” to a new one “Vrdm1n” in consideration of a shift amount of the threshold voltage distribution S12 by the verification voltage “Vvref1n”. Moreover, because the interval between the threshold voltage distributions S12 and S14 is secured due to the absence of the threshold voltage distribution S13 during the lifetime extension mode as described with reference to FIGS. 6A and 9A, the processor 110 may re-set the read voltage from a current one “Vrdl1” to a new one “Vrdl1n”. In addition, because it is not necessary to identify the threshold voltage distribution S18 due to the absence of the threshold voltage distribution S18 during the lifetime extension mode as described with reference to FIGS. 6A and 9A, the read voltage Vrdl2 to identify the threshold voltage distribution S18 may not be used.

According to the embodiment, when read voltages are re-set as shown in FIG. 11B, since read margins between threshold voltage distributions are increased, occurrence of an error may be prevented.

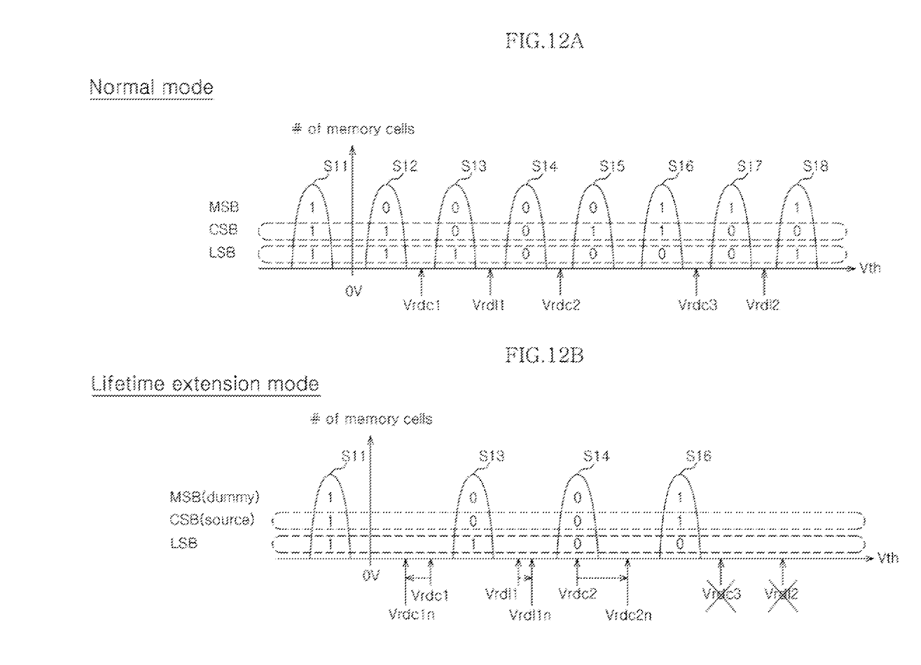

FIG. 12A is a diagram of the threshold voltage distribution of memory cells exemplarily illustrating the read operation to LSB and CSB pages of the data storage device 10 shown in FIG. 1 during the normal mode.

Referring to FIG. 12A, the nonvolatile memory apparatus 200 may use the read voltages Vrdl1 and Vrdl2 when performing the read operation for the LSB page during the normal mode. For example, the nonvolatile memory apparatus 200 may determine that LSB data “1” is stored in the memory cell when the threshold voltage of the memory cell is less than the read voltage Vrdl1, that LSB data “0” is stored in the memory cell when the threshold voltage of the memory cell is greater than the read voltage Vrdl1 and less than the read voltage Vrdl2, and that LSB data “1” is stored in the memory cell when the threshold voltage of the memory cell is greater than the read voltage Vrdl2.

Further, the nonvolatile memory apparatus 200 may use the read voltages Vrdc1, Vrdc2 and Vrdc3 when performing the read operation for the CSB page during the normal mode. For example, the nonvolatile memory apparatus 200 may determine that CSB data “1” is stored in the memory cell when the threshold voltage of the memory cell is less than the read voltage Vrdc1, that CSB data “0” is stored in the memory cell when the threshold voltage of the memory cell is greater than the read voltage Vrdc1 and less than the read voltage Vrdc2, that CSB data “1” is stored in the memory cell when the threshold voltage of the memory cell is greater than the read voltage Vrdc2 and less than the read voltage Vrdc3, and that CSB data “0” is stored in the memory cell when the threshold voltage of the memory cell is greater than the read voltage Vrdc3.

FIG. 12B is a diagram of the threshold voltage distribution of memory cells exemplarily illustrating the read operation to LSB and CSB pages of the data storage device 10 shown in FIG. 1 during the lifetime extension mode. FIG. 12B shows where the processor 110 stores the data, which is already stored or is currently to be stored in the CSB page, in the MSB page as the dummy data as described above with reference to FIG. 6B.

The processor 110 may re-set one or more read voltages for the nonvolatile memory apparatus 200 to perform the read operation for the LSB page and the CSB page during the lifetime extension mode. The processor 110 may re-set the read voltages before reading data during the lifetime extension mode. The processor 110 may transmit a read voltage reset command to the nonvolatile memory apparatus 200 for the read operation with the re-set read voltages. The processor 110 may back up the re-set read voltages in the nonvolatile memory apparatus 200 to subsequently and continuously use the re-set read voltages.

Referring to FIG. 12B, when the verification voltage Vvrf3n for the threshold voltage distribution S14 is re-set as described above with reference to FIG. 9B, the processor 110 may re-set the read voltage from a current one “Vrdl1” to a new one “Vrdl1n” in consideration of a shift amount of the threshold voltage distribution S14 by the verification voltage “Vvref3n”. Moreover, because the interval between the threshold voltage distributions S14 and S16 is changed due to the shift of the threshold voltage distribution S14 and due to the absence of the threshold voltage distribution S15 during the lifetime extension mode as described with reference to FIGS. 6B and 9B, the processor 110 may re-set the read voltage from a current one “Vrdc2” to a new one “Vrdc2n”. In addition, because the interval between the threshold voltage distributions S11 and S13 is secured due to the absence of the threshold voltage distribution S12 during the lifetime extension mode as described with reference to FIGS. 6B and 9B, the processor 110 may re-set the read voltage from a current one “Vrdc1” to a new one “Vrdc1n”. Also, because it is not necessary to identify the threshold voltage distributions S17 and S18 due to the absence of the threshold voltage distributions S17 and S18 during the lifetime extension mode as described with reference to FIGS. 6B and 9B, the read voltages Vrdc3 and Vrdl2 to identify the threshold voltage distributions S17 and S18 may not be used.

According to the embodiment, when read voltages are set as shown in FIG. 12B, since read margins between threshold voltage distributions are increased, occurrence of an error may be prevented.

While various embodiments have been described above, it will be understood to those skilled in the art that the embodiments described are examples only. Accordingly, the data storage device and the operating method thereof described herein should not be limited based on the described embodiments.

What is claimed is:

1. A data storage device comprising:
a nonvolatile memory apparatus including a plurality of pages coupled to a single word line; and
a controller suitable for accessing the nonvolatile memory apparatus during one of first and second modes,
wherein the second mode is enabled when the nonvolatile memory apparatus has reached a lifetime limit, and
wherein the controller stores the same data in both of a source page and a dummy page during the second mode.

2. The data storage device according to claim 1, wherein, during the first mode, the controller stores the data in the plurality of pages according to a gray code scheme.

3. The data storage device according to claim 1, wherein, during the second mode, the controller stores data in the plurality of pages, but not in the dummy page, according to a gray code scheme.

4. The data storage device according to claim 1, wherein, during the second mode, the controller re-sets one or more verification voltages for the nonvolatile memory apparatus to perform a write verification operation.

5. The data storage device according to claim 1, wherein, during the second mode, the controller re-sets one or more read voltages for the nonvolatile memory apparatus to perform a read operation.

6. The data storage device according to claim 1, wherein the controller comprises an apparatus lifetime management section suitable for detecting when the nonvolatile memory apparatus has reached the lifetime limit based on a number of erase operations performed by the nonvolatile memory apparatus.

7. An operating method for a data storage device including a nonvolatile memory apparatus which includes a plurality of pages coupled to a single word line, the operating method comprising:
storing data in the plurality of pages during a first mode;
enabling a second mode by detecting that the nonvolatile memory apparatus has reached a lifetime limit; and
storing data in the plurality of pages during the second mode,
wherein the storing of the data in the plurality of pages during the second mode comprises storing the same data in both of a source page and a dummy page.

8. The operating method according to claim 7, wherein the storing of the data in the plurality of pages during the first mode stores the data in the plurality of pages according to a gray code scheme.

9. The operating method according to claim 7, wherein the storing of the data in the plurality of pages during the second mode s stores data in the plurality of pages, but not in the dummy page, according to a gray code scheme.

10. The operating method according to claim 7,
further comprising re-setting one or more verification voltages during the second mode,
wherein the storing of the data in the plurality of pages during the second mode comprises performing a write verification operation with the re-set verification voltages.

11. The operating method according to claim 7, further comprising:
re-setting one or snore read voltages during the second mode, and
performing a read operation with the re-set read voltages.

12. The operating method according to claim 7, wherein the enabling of the second mode detects when the nonvolatile memory apparatus has reached the lifetime limit based on a number of erase operations performed by the nonvolatile memory apparatus.

13. The operating method according to claim 7, wherein the storing of the same data in both of the source page and the dummy page stores data, which is already stored or is currently to be stored in the source page, also in the dummy page.

14. A data storage device comprising:
a nonvolatile memory apparatus including a plurality of pages coupled to a single word line; and
a controller suitable for accessing the nonvolatile memory apparatus during one of first and second modes,
wherein a number of threshold voltage distributions of memory cells during the second mode is less than that during the first mode.

15. The data storage device according to claim 14, wherein, during the first mode, the controller stores data in the plurality of pages according to a gray code scheme.

16. The data storage device according to claim 14,
wherein the controller stores a part of data in both of a source page and a dummy page during the second mode, and
wherein, during the second mode, the controller stores data in the plurality of pages, but not in the dummy page, according to a gray code scheme.

17. The data storage device according to claim 14, wherein, during the second mode, the controller re-sets one or more verification voltages for the nonvolatile memory apparatus to perform a write verification operation.

18. The data storage device according to claim 14, wherein, during the second mode, the controller re-sets one or more read voltages for the nonvolatile memory apparatus to perform a read operation.

19. The data storage device according to claim 14, wherein the controller comprises an apparatus lifetime management section suitable for detecting when the nonvolatile memory apparatus has reached the lifetime limit based on a number of erase operations performed by the nonvolatile memory apparatus.
